(19) United States
(12) Patent Application Publication
(10) Pub. No.: US 2024/0224485 A1
(43) Pub. Date: Jul. 4, 2024

(54) INSPECTION SYSTEM, INSPECTION MANAGEMENT DEVICE, INSPECTION PROGRAM CREATING METHOD, AND PROGRAM

(71) Applicant: OMRON Corporation, Kyoto-shi, KYOTO (JP)

(72) Inventor: Takako ONISHI, Kyoto-shi, KYOTO (JP)

(21) Appl. No.: 18/547,003

(22) PCT Filed: Jan. 19, 2022
(86) PCT No.: PCT/JP2022/001723

§ 371 Date: Feb. 21, 2024

(30) Foreign Application Priority Data
Mar. 15, 2021 (JP) 2021-041202

(51) Int. Cl. H05K 13/08; G06T 7/00

(52) U.S. Cl. CPC H05K 13/083; G06T 7/0006; G06T 2207/10116; G06T 2207/20081; G06T 2207/30164

(57) ABSTRACT

An inspection system includes (1+n) types of imaging units each configured to capture an image of a substrate that is an inspection target and acquire image data, (1+m) types of inspection units each configured to perform, on the basis of (1+n) types of the image data respectively acquired by the (1+n) types of imaging units, an inspection suitability calculation unit configured to calculate, for each of inspection items related to each of components mounted on the substrate, inspection suitabilities each indicating a suitability of each of (1+m) types of the inspections performed by the (1+m) types of inspection units for detecting an abnormality according to the inspection item, and an inspection program creation unit configured to determine, on the basis of the inspection suitabilities, whether to perform each of the (1+m) types of inspections for each of the inspection items related to each of the components mounted on the substrate.

### TECHNICAL FIELD

The present invention relates to an inspection system, an inspection management device, an inspection program creation method, and a program.

### BACKGROUND ART

In manufacturing processes of various substrates, the substrate is measured and inspected using an image obtained by imaging the substrate. There is known a system where, if inspection is to be performed by a plurality of types of inspection devices, inspection items specified for each component on the substrate are divided among the plurality of inspection devices (Patent Document 1).

Patent Document 1 discloses a technique in which, in the substrate inspection system including a plurality of types of inspection devices, an inspection device is selected for each component on the substrate subject to inspection or for each inspection item requiring inspection, and these selections are reflected in an inspection program at each of the inspection devices. With this configuration, it is possible to reduce the occurrence of the same inspection item being unnecessarily redundantly set across a plurality of inspection devices or an inspection item not being inspected by any of the inspection devices.

### CITATION LIST

### Patent Literature

Patent Document 1: JP 2012-151250 A (JP 5522065 B)

### SUMMARY OF INVENTION

### Technical Problem

In the technique described in Patent Document 1, as for which inspection device is to inspect what inspection item of which component, the inspection device to inspect each inspection item is determined on the basis of design information, such as the type of component and the placement of the component on the substrate. However, at the time of actual inspection, factors such as the state of each component mounted on the substrate and the state of each inspection device may unexpectedly influence the inspection. As a result, allocation of the inspection items as described above may not necessarily be optimal for inspection accuracy and efficiency.

The present invention has been made in view of the above circumstances, and an object thereof is to provide a technique for improving inspection accuracy and efficiency in an inspection system of a component-mounted substrate that includes a plurality of types of inspection devices.

### Solution to Problem

To achieve the object described above, the present invention employs the following configuration. That is, an inspection system includes (1+n) types of imaging units each configured to capture an image of a component-mounted substrate that is an inspection target and acquire image data, (1+m) types of inspection units each configured to perform, on the basis of (1+n) types of the image data respectively acquired by the (1+n) types of imaging units, an inspection corresponding to each of the (1+n) types of image data, an inspection suitability calculation unit configured to calculate, for each of inspection items related to each of components mounted on the component-mounted substrate, inspection suitabilities each indicating a suitability of each of (1+m) types of the inspections performed by the (1+m) types of inspection units for detecting an abnormality according to the inspection item, and an inspection program creation unit configured to create or update an inspection program for the component-mounted substrate. The inspection program creation unit determines, on the basis of the inspection suitabilities, whether to perform each of the (1+m) types of inspections for each of the inspection items related to each of the components mounted on the component-mounted substrate.

The “imaging unit” herein is not limited to a camera that detects a wavelength in a visible light region and may also be an X-ray camera that detects X-rays or a photomultiplier sensor used for laser scanning. Further, the “inspection unit” is a device that performs inspection on the basis of image data obtained by imaging the inspection target, such as a device that performs automatic optical inspection (AOI) or a device that performs automatic X-ray inspection (AXI), for example. Further, the “inspection item” described above may include information such as coordinates at which the inspection is performed and a parameter for extracting an inspection target. Furthermore, in the above description, n may be equal to m.

With such a configuration, in the substrate inspection system including a plurality of types of inspection units, it is possible to calculate suitabilities for an inspection item specified for each component of the substrate on the basis of a difference in measurement principles of the inspection units and to configure the inspection program such that inspection of the inspection item is assigned to an inspection unit in accordance with the suitabilities (that is, to the inspection unit having the highest suitability). This makes it possible to improve inspection reliability (accuracy) and efficiency (speed).

Further, the inspection system may further include a sample image acquisition unit configured to acquire (1+n) types of sample images of the component-mounted substrate respectively captured by the (1+n) types of imaging units, and the inspection suitability calculation unit may include a first suitability calculation unit configured to calculate the inspection suitabilities on the basis of the (1+n) types of sample images.

With such a configuration, it is possible to calculate which inspection unit is more suitable for performing an inspection with reference to the way the component subject to inspection is actually imaged on the basis of the images captured using the actual inspection devices. For example, although an appearance inspection is generally suitable for inspecting the shape of a component visible from the outside (and a solder fillet around the component), in an image actually captured by a visible light camera, secondary reflection may be present in the fillet, the component may be in a blind spot due to another component, or luminance insufficiency/saturation may be present. In such a case, the suitability of the appearance inspection deteriorates (compared with general assumptions). Thus, determining the suitability in consideration of such information makes it possible to calculate a more accurate suitability. Further, by configuring the inspection program on the basis of the suitabilities, the accuracy of inspection can be improved.

Further, the first suitability calculation unit may include a trained model obtained by performing machine learning using a training data set including inspection image data related to the component-mounted substrate resulting in a false negative and/or a false positive in at least any one of the (1+m) types of inspections performed in the past.

Note that “false negative” means a so-called missed defect, and false positive means so-called overdetection. With such a configuration, the suitabilities can be calculated efficiently by using a training model trained on the basis of past performance data.

Further, the inspection system may further include an inspection history acquisition unit configured to acquire inspection history information of the past including an inspection result of false negative and/or false positive related to components of the same types as the components mounted on the component-mounted substrate, and the inspection suitability calculation unit may include a second suitability calculation unit configured to calculate the inspection suitabilities on the basis of the inspection history information.

The “components of the same types” as used herein is not limited to components having the same component number but also includes other components having similar shapes, applications, and the like. With such a configuration, the suitabilities can be calculated more accurately by determining, for each inspection unit, a suitability for an inspection item of a component for which a false negative or a false positive is likely to occur (has a large number of actual results) in consideration of such actual results.

Further, the inspection system may further include a design information acquisition unit configured to acquire design information related to the component-mounted substrate, and the inspection suitability calculation unit may include an initial value calculation unit configured to calculate initial values of the inspection suitabilities on the basis of the design information.

For each inspection item of each component mounted on the substrate, general knowledge has been acquired for estimating which inspection unit is suitable for performing inspection in light of design information such as placement relationships between components and sizes of the components on the substrate. Therefore, on the basis of such knowledge, the suitabilities for the first inspection and the second inspection can be calculated for each inspection item of each component mounted on the component-mounted substrate subject to inspection, and set the calculated suitabilities as the initial values. Thus, the suitabilities can be calculated relatively easily, and the accuracy of the inspection can be improved by appropriately calculating more accurate suitabilities according to the actual situation of the inspection and then updating the initial values.

Further, the inspection suitabilities are individually calculated in correspondence with each of the (1+m) types of inspections, and the inspection suitability calculation unit may calculate the inspection suitabilities of all of the (1+m) types of inspections for each of the inspection items related to each of the components.

Specifically, for example, for each of the (1+m) types of inspections, the inspection suitabilities may be calculated using values in ten stages from 1 to 10. Thus, for each inspection, it is possible to calculate the suitabilities according to the actual situation and compare the calculated suitabilities and then determine how to divide the inspections for each inspection item, and more accurately reflect the inspection suitabilities in the inspection program. However, how to indicate the inspection suitabilities is not limited to the manner of indication described above. For example, the suitabilities may be indicated by a ratio of a suitability of one inspection to a suitability of another inspection, or may be indicated by assigning values such that the total sum of the inspection suitabilities of all inspections is always 100. Further, the suitabilities may be indicated by rankings for all inspections.

Further, the inspection program creation unit may determine whether to perform the (1+m) types of inspections for each of the inspection items related to each of the components on the basis of the inspection suitabilities such that at least any one of the (1+m) types of inspections is performed for each of the inspection items related to each of the components mounted on the component-mounted substrate and all of the (1+m) types of inspections are performed for the inspection item for which none of the inspection suitabilities of the (1+m) types of inspections has met a predetermined criterion.

For an efficient inspection, it is preferable to avoid redundantly performing an inspection across a plurality of inspection units. However, to perform an accurate inspection, a required number of inspections needs to be performed on all components. In this regard, with a configuration such as described above, in a case in which the suitabilities are such that the inspection accuracy cannot be ensured in any of the inspections, coverage can be ensured by redundantly executing all of the inspections.

Further, the inspection program creation unit may be configured to determine to perform any one of the (1+m) types of inspections to minimize line takt related to inspection of the component-mounted substrate for the inspection item for which a difference between the inspection suitabilities of the (1+m) types of inspections is within a predetermined range.

If the first inspection unit and the second inspection unit can be used because the suitabilities for the first inspection and the second inspection each indicate an unproblematic value, that is, if the accuracies of the inspections are ensured, it is preferable to create the inspection program such that which inspection unit is suitable for performing inspection of the inspection item is determined such that the line takt of the entire inspection process is minimized (that is, improves efficiency). Specifically, inspection can be allocated on the basis of a criterion that will not create a bottleneck such that the inspection is performed by a unit that, if allocated the inspection of the inspection item, will not increase the imaging field number or, with reference to past history information related to the time required for inspection or the like.

Further, the (1+n) types of imaging units may include a first imaging unit that is a visible light camera and a second imaging unit that is an X-ray camera, and the (1+m) types of inspections may include a first inspection based on first image data acquired by the first imaging unit and a second inspection based on second image data acquired by the second imaging unit. The combination of these inspection units is suitable for inspection of a component-mounted substrate.

Further, the present invention can also be regarded as an inspection management device that is a device configured to manage an inspection by an inspection system including (1+n) types of imaging units each configured to capture an image of a component-mounted substrate that is an inspection target and acquire image data and (1+m) types of inspection units each configured to perform, on the basis of (1+n) types of the image data respectively acquired by the (1+n) types of imaging units, an inspection corresponding to each of the (1+n) types of image data. The inspection management device includes an inspection suitability calculation unit configured to calculate, for each of inspection items related to each of components mounted on the component-mounted substrate, inspection suitabilities each indicating a suitability of each of (1+m) types of the inspections performed by the (1+m) types of inspection units for detecting an abnormality according to the inspection item, and an inspection program creation unit configured to create or update an inspection program for the component-mounted substrate. The inspection program creation unit is configured to determine, on the basis of the inspection suitabilities, whether to perform each of the (1+m) types of inspections for each of the inspection items related to each of the components mounted on the component-mounted substrate.

Further, the present invention can also be regarded as an inspection program creation method for an inspection system including (1+n) types of imaging units each configured to capture an image of a component-mounted substrate that is an inspection target and acquire image data and (1+m) types of inspection units each configured to perform, on the basis of (1+n) types of the image data respectively acquired by the (1+n) types of imaging units, an inspection corresponding to each of the (1+n) types of image data. The inspection program creation method includes an inspection suitability calculation step of calculating, for each of inspection items related to each of components mounted on the component-mounted substrate, inspection suitabilities each indicating a suitability of each of (1+m) types of the inspections performed by the (1+m) types of inspection units for detecting an abnormality according to the inspection item, and an execution inspection determination step of determining, on the basis of the inspection suitabilities, whether to perform each of the (1+m) types of inspections for each of the inspection items related to each of the components mounted on the component-mounted substrate.

Further, the inspection program creation method may further include a sample image acquisition step of acquiring (1+n) types of sample images of the component-mounted substrate respectively captured by the (1+n) types of imaging units, and the inspection suitability calculation step may include a first suitability calculation step of calculating the inspection suitabilities on the basis of the (1+n) types of sample images.

Further, the inspection program creation method may further include an inspection history acquisition step of acquiring inspection history information of the past including an inspection result of false negative and/or false positive related to components of the same types as the components mounted on the component-mounted substrate, and the inspection suitability calculation step may include a second suitability calculation step of calculating the inspection suitabilities on the basis of the inspection history information.

Further, the inspection program creation method may further include a design information acquisition step of acquiring design information related to the component-mounted substrate, and the inspection suitability calculation step may include an initial value calculation step of calculating initial values of the inspection suitabilities on the basis of the design information.

Further, the present invention can also be regarded as a program for causing a computer to execute the method described above, and a computer readable storage medium in which such a program is recorded in a non-transitory manner.

Note that each of the configurations and processes described above can be combined to constitute the present invention as long as there is no technical contradiction.

### Advantageous Effects of Invention

According to the present invention, it is possible to provide a technique for improving inspection efficiency and accuracy in an inspection system of a component-mounted substrate that includes a plurality of types of inspection devices.

### BRIEF DESCRIPTION OF DRAWINGS

FIG. 1 is a schematic view illustrating a schematic configuration of an inspection system according to an application example.

FIG. 2 is a block diagram illustrating a schematic configuration of the inspection system according to an embodiment.

FIG. 3 is a flowchart illustrating a flow of inspection program creation in the inspection system according to the embodiment.

### DESCRIPTION OF EMBODIMENTS

Hereinafter, an implementation example according to the present invention will be described with reference to the drawings. However, dimensions, materials, shapes, relative arrangements, and the like of constituent elements described in the following example are not intended to limit the scope of the present invention unless otherwise specified.

### Application Example

### (Configuration of Application Example)

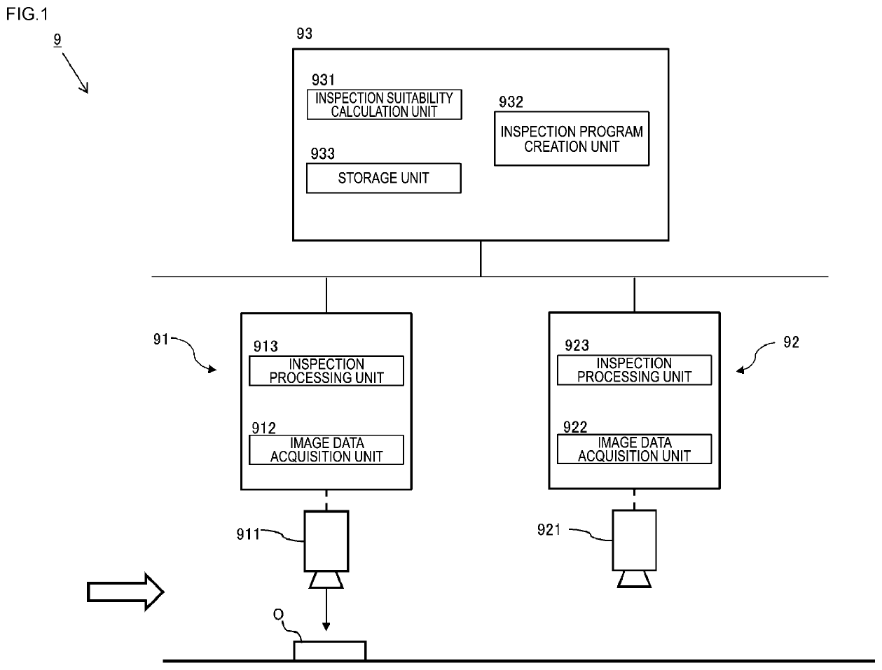

The present invention can be applied as, for example, an inspection management device for creating an inspection program for a substrate inspection system. FIG. 1 is a schematic view illustrating a schematic configuration of the substrate inspection system to which the present invention is applied. As illustrated in FIG. 1, a substrate inspection system 9 according to the present application example includes a plurality of inspection devices 91, 92 arranged on a production line (not illustrated) of a component-mounted substrate, an inspection management device 93 that manages content and results of inspections, and a communication line such as a local area network (LAN) that connects these components to one another. Note that, in this application example, a system including two types of imaging units and inspection devices respectively including the imaging units will be described as an example, but the quantities of the imaging units and the inspection devices are not limited thereto.

The inspection devices 91, 92 each inspect a component-mounted substrate O, which is an inspection target, on the basis of image data obtained by an imaging unit imaging the component-mounted substrate, which is transported from the production line by a transport roller (not illustrated). As illustrated in FIG. 1, the inspection devices 91, 92 include imaging units 911, 921, image data acquisition units 912, 922, and inspection processing units 913, 923, respectively. Note that the white arrow in FIG. 1 indicates a direction in which the component-mounted substrate O is transported.

In this example, different types of imaging units are employed as the imaging unit 911 of the inspection device 91 and the imaging unit 921 of the inspection device 92. For example, the imaging unit 911 may be a visible light camera and the imaging unit 921 may be an X-ray camera. Further, in each inspection device, the component-mounted substrate O is inspected by the inspection processing unit using a predetermined inspection program to judge whether the image data obtained by the imaging units and the image data acquisition units passes or fails.

The inspection management device 93 can be constituted by, for example, a general-purpose computer and includes functional units of an inspection suitability calculation unit 931, an inspection program creation unit 932, and a storage unit 933. In addition, although not illustrated, various input units, such as a mouse and a keyboard, and output units, such as a display, are provided.

The inspection suitability calculation unit 931 calculates, for each inspection item related to each component mounted on the component-mounted substrate O, inspection suitabilities indicating suitabilities of inspection by the inspection device 91 and inspection by the inspection device 92 for detecting an abnormality according to the inspection item. A specific calculation method will be described below.

Further, the inspection program creation unit 932 creates an inspection program for inspection processing performed by the inspection devices 91, 92. In this example, the created inspection program includes flag information indicating whether inspections of inspection items related to each component mounted on the inspection device component-mounted substrate O are to be performed by each of the inspection devices 91, 92. That is, if the flag is ON, the inspection device performs inspection of the inspection item subject to inspection and, if the flag is OFF, the inspection device does not perform the inspection. Note that the term “create” a program as used herein includes not only creation from scratch but also creation by updating an existing program.

The storage unit 933 is constituted by a storage unit such as a random access memory (RAM) and a hard disk drive (HDD), and stores various kinds of information such as various kinds of design information related to the component-mounted substrate O (mounted components, placement relationships between components, etc.), component-related information (component type, component number, lot number, component image, etc.), an inspection program (inspection items, inspection criteria, etc.), past inspection image data, and past inspection result information.

### (Calculation of Inspection Suitability)

Next, the suitability calculation performed by the inspection suitability calculation unit 931 in the present application example will be described. The inspection suitability calculation unit 931 sets initial values of suitabilities for performing inspections (that is, a degree to which an abnormality can be appropriately detected) by each of the inspection devices 91, 92 for each component mounted on the component-mounted substrate O and for each inspection item of each component, on the basis of various kinds of design information related to the component-mounted substrate O stored in the storage unit 933. For example, for an inspection item for a component color or a character section printed on a component, for example, for “wrong product number,” inspection cannot be performed using an image captured by an X-ray camera. Thus, the inspection suitability of an X-ray inspection device is 0. On the other hand, a bottom surface mounted component (ball grid array (BGA)) of a substrate cannot be inspected using a visible light image obtained by imaging an upper surface of the substrate. Thus, the inspection suitability of an appearance inspection device is 0.

The inspection suitability calculation unit 931 further performs a process of updating the set initial values in accordance with the actual inspection environment. For example, images of non-defective samples (hereinafter, simply referred to as sample images) captured in advance by the inspection devices 91, 92 can be acquired, and the suitabilities can be corrected on the basis of the sample images so as to reflect the actual state. For example, if luminance insufficiency or saturation is present in an acquired sample image, the inspection suitability of the inspection device that captured the sample image is corrected downward.

The inspection suitability calculation unit 931 thus calculates, for each inspection item related to each component mounted on the component-mounted substrate O, inspection suitabilities indicating suitabilities of inspection by the inspection device 91 and inspection by the inspection device 92 for detecting an abnormality according to the inspection item.

Then, the inspection program creation unit 932 creates an inspection program on the basis of the inspection suitabilities calculated as above. In this example, the inspection suitabilities are utilized for determining how to divide the inspection items such that inspections are not redundantly performed by the inspection device 91 and the inspection device 92 to the extent possible, while ensuring coverage such that a required number of inspections is performed for all components mounted on the component-mounted substrate O.

Note that the inspection program created by the inspection program creation unit 932 is transmitted to each of the inspection devices 91, 92, and the inspection of the component-mounted substrate O is started according to the inspection program created on the basis of the inspection suitabilities.

According to the inspection management system 9 as described above, inspection by a plurality of inspection devices each including different imaging systems can be divided between individual inspection items and performed for each inspection item in accordance with the suitabilities. As a result, both inspection accuracy and inspection efficiency can be improved in a compatible manner.

### Embodiments

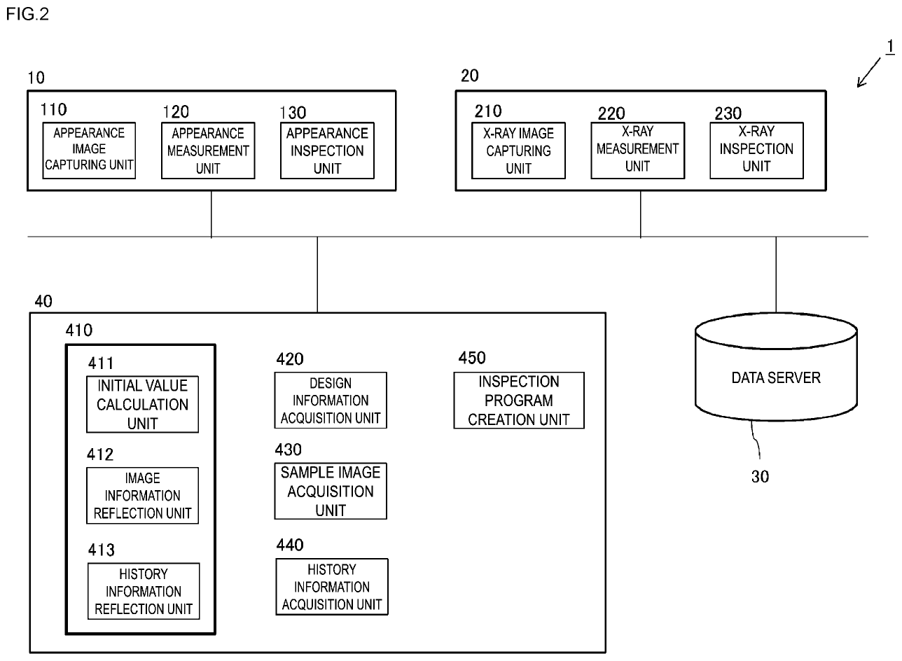

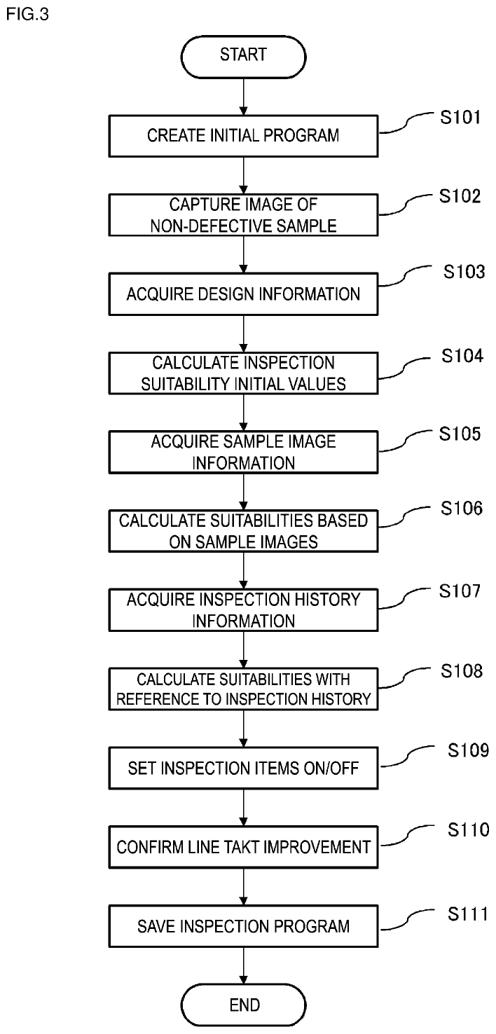

Hereinafter, an embodiment according to the present invention will be described in more detail with reference to FIGS. 2 and 3, taking as an example a system for inspecting a substrate by an appearance inspection device and an X-ray inspection device.

### (System Configuration)

FIG. 2 is a block diagram illustrating an overview of a configuration of a substrate inspection system 1 according to the present embodiment. The substrate inspection system 1 according to the present embodiment generally includes an appearance inspection device 10, an X-ray inspection device 20, a data server 30, and an inspection management device 40. These components are communicably connected to one another by a communication unit (not illustrated).

The appearance inspection device 10 is, for example, a device that performs an appearance inspection on a component-mounted substrate using an inspection method that is a combination of a so-called phase shift method and a color highlight method. The inspection method that is a combination of the phase shift method and the color highlight method is a known technique and therefore a detailed description will not be provided. Performing such an inspection makes it possible to accurately detect the shape of an electrode recognizable from the appearance and a degree of inclination of a fillet in a land portion of the substrate. Note that the phase shift method is one technique for reconstructing a three-dimensional shape of an object surface by projecting pattern light onto the object surface and analyzing distortion of the pattern. Further, the color highlight method is a method of representing a three-dimensional shape of a solder surface as two-dimensional hue information by irradiating the substrate with light of a plurality of colors (wavelengths) at different angles of incidence and capturing an image of the substrate in a state in which color features (colors of light sources in a specular reflection direction when viewed from a camera) corresponding to a normal direction of the solder surface appear on the solder surface.

The appearance inspection device 10 generally includes functional units such as an appearance image capturing unit 110, an appearance measurement unit 120, and an appearance inspection unit 130 as well as a projector, a light source, and a stage for holding a substrate (none of which are illustrated). The appearance image capturing unit 110 captures an image of the substrate irradiated with light from the projector and the light source (not illustrated) and outputs an appearance inspection image. The appearance measurement unit 120 measures an appearance shape of (a mounted component on) the substrate on the basis of the appearance inspection image. The appearance inspection unit 130 inspects the appearance, that is, judges whether the (mounted component on the) substrate passes or fails by comparing the measured appearance shape and the inspection criterion. Note that, in the following description, the phrase “inspection of substrate” also includes the inspection of components mounted on the substrate.

Note that information related to the appearance inspection image, the measurement value of the appearance shape, and the appearance inspection result is transmitted from the appearance inspection device 10 to the data server 30 and stored in the data server 30.

The X-ray inspection device 20 is, for example, a device that measures the three-dimensional shape of the substrate by a method such as computed tomography (CT) or tomosynthesis, and judges whether the substrate passes or fails on the basis of the three-dimensional shape.

The X-ray inspection device 20 generally includes functional units such as an X-ray image capturing unit 210, an X-ray measurement unit 220, and an X-ray inspection unit 230 as well as an X-ray source and a stage for holding the substrate (neither of which are illustrated). The X-ray image capturing unit 210 captures an image of X-rays emitted from an X-ray source (not illustrated) and transmitted through the substrate, and outputs a tomographic image (hereinafter referred to as an X-ray image) of the substrate. The X-ray measurement unit 220 measures the three-dimensional shape of the substrate on the basis of a plurality of the X-ray images. The X-ray inspection unit 230 inspects the three-dimensional shape, that is, judges whether the substrate passes or fails by comparing the measured three-dimensional shape and the inspection criterion.

Note that the information related to the X-ray image, the three-dimensional shape data, and the X-ray inspection result described above is transmitted from the X-ray inspection device 20 to the data server 30 and stored in the data server 30.

The inspection management device 40 may be, for example, a general-purpose computer. That is, although not illustrated, the inspection management device 40 includes a processor such as a central processing unit (CPU) or a digital signal processor (DSP), a storage unit including a main storage unit such as a read-only memory (ROM) or a random access memory (RAM), an auxiliary storage unit such as an erasable programmable read-only memory (EPROM), a hard disk drive (HDD), or a removable medium, an input unit such as a keyboard or a mouse, and an output unit such as a liquid crystal display. Note that the inspection management device 40 may be constituted by a single computer or may be constituted by a plurality of computers that work in conjunction with one another.

The auxiliary storage unit stores an operating system (OS), various programs, various kinds of information related to the inspection target, various inspection criteria, and the like, the programs stored therein are loaded into a work area of the main storage unit and executed, and the components and the like are controlled through execution of the programs, whereby functional units that achieve predetermined purposes such as those described below can be realized. Note that some or all of the functional units may be realized by a hardware circuit such as an application-specific integrated circuit (ASIC) or a field-programmable gate array (FPGA).

Next, each functional unit included in the inspection management device 40 will be described. The inspection management device 40 includes functional units of an inspection suitability calculation unit 410, a design information acquisition unit 420, a sample image acquisition unit 430, a history information acquisition unit 440, and an inspection program creation unit 450.

As will be described below, the inspection suitability calculation unit 410 calculates the inspection suitabilities on the basis of information acquired by the design information acquisition unit 420, the sample image acquisition unit 430, and the history information acquisition unit 440. The inspection suitabilities are degrees indicating suitabilities of inspection by the appearance inspection device 10 and inspection by the X-ray inspection device 20 for detecting, for each inspection item related to each component mounted on the substrate, an abnormality according to the inspection item. In the present embodiment, an appearance inspection suitability indicating the suitability of inspection by the appearance inspection device 10 and an X-ray inspection suitability indicating the suitability of inspection by the X-ray inspection device 20 are each calculated as a value from 0 to 10.

Note that, more specifically, the inspection suitability calculation unit 410 further includes functional units of an initial value calculation unit 411, an image information reflection unit 412, and a history information reflection unit 413.

The design information acquisition unit 420 acquires, from the data server 30, design information of the substrate, such as shapes and sizes of components mounted on the substrate subject to inspection (and lands), and placement relationships between the components. Further, the sample image acquisition unit 430 acquires, from the data server 30, sample image data obtained by imaging, by the appearance inspection device 10 and the X-ray inspection device 20, a non-defective sample of the substrate subject to inspection. Further, the history information acquisition unit 440 acquires, from the data server 30, information of past inspection history including inspection results of false negatives and/or false positives related to components of the same types as the components mounted on the substrate. Note that the phrase “components of the same type” as used herein is not limited to components having the same component number but also includes other components having similar shapes, applications, and the like.

The inspection program creation unit 450 creates an inspection program for inspection processing performed by the appearance inspection device 10 and the X-ray inspection device 20. Creation of the inspection program will be described in detail below. Note that the term “create” a program as used herein includes not only creation from scratch but also creation by updating an existing program.

The initial value calculation unit 411 calculates initial values of the inspection suitabilities on the basis of the design information acquired by the design information acquisition unit 420. Specifically, for an inspection item that requires identification of a component color or characters printed on a component, for example, for “wrong product number,” X-ray inspection cannot be applied. Thus, the X-ray inspection suitability is set to 0 and the appearance inspection suitability is set to 10. On the other hand, for an inspection item related to a component to which an appearance inspection cannot be applied, such as a component mounted on the bottom surface of the substrate or a component covered with a shield, the appearance inspection suitability is set to 0 and the X-ray inspection suitability is set to 10. In addition, for example, for an inspection related to a solder shape such as an inspection related to a front fillet, the suitabilities may be set such that the appearance inspection suitability is higher than the X-ray inspection suitability (e.g., appearance inspection suitability=7, X-ray inspection suitability=4). However, even for an inspection item related to a solder shape, the appearance inspection suitability is set low for an inspection item of a target component which is likely to be located in an appearance inspection blind spot or to be affected by secondary reflection from the fillet of an adjacent component due to the positional relationship between the target component and an adjacent component.

The image information reflection unit 412 uses the data acquired by the sample image acquisition unit 430 to calculate corrected inspection suitabilities obtained by correcting the initial values of the inspection suitabilities calculated by the initial value calculation unit 411. Specifically, for example, in a case in which there is a component for which secondary reflection or a blind spot is confirmed in a sample image of the appearance inspection, or in a case in which luminance insufficiency or saturation is present in the image, a corrected inspection suitability obtained by downward correcting the appearance inspection suitability related to the component is calculated. Further, for the X-ray inspection suitability as well, in a case in which noise caused by a component on a rear surface of the substrate is significant in a sample image of the X-ray inspection, for example, a corrected inspection suitability obtained by downward correcting the X-ray inspection suitability is calculated. Note that such processing based on a sample image may be performed by making a judgment on the basis of the luminance or noise amount in image processing of the sample image, or may be obtained by inputting the sample image to a trained model trained on the basis of past inspection results. In the present embodiment, the image information reflection unit 412 corresponds to a first suitability calculation unit.

The history information reflection unit 413 calculates corrected inspection suitabilities obtained by further correcting the initial values of the inspection suitabilities or further correcting the corrected inspection suitabilities by using the information of the past inspection history acquired by the history information acquisition unit 440. Specifically, for example, in a case in which overdetection has frequently occurred in past appearance inspections of the same type of component as the inspection target, a corrected inspection suitability obtained by downward correcting the appearance inspection suitability may be calculated. Note that, in a case in which there is no particular history information to be reflected, the history information reflection unit 413 does not need to calculate the corrected inspection suitability. In the present embodiment, the history information reflection unit 413 corresponds to a second suitability calculation unit.

### (Inspection Program Creation Processing)

Next, a flow of processing for creating the inspection program in the inspection management system 1 according to the present embodiment will be described with reference to FIG. 3. FIG. 3 is a flowchart illustrating the flow of processing. As illustrated in FIG. 3, first, components subject to inspection, inspection items for the components, inspection criteria serving as criteria for pass/fail judgment with respect to the inspection items, and the like are registered, and an initial program is created (S101). This processing may be performed by manual input by a user or may be performed by the inspection program creation unit 450 of the inspection management device 40.

Next, images of a non-defective sample of the substrate are captured by the appearance inspection device 10 and the X-ray inspection device 20, and the sample image data is stored in the data server 30 (S102).

Next, the inspection management device 40 uses the design information acquisition unit 420 to acquire design information of the substrate subject to inspection from the data server 30 (S103). Note that, in a case in which the design information of the substrate subject to inspection is not stored in the data server 30 in advance, the design information may be registered at this stage. Subsequently, the inspection management device 40 uses the initial value calculation unit 411 of the inspection suitability calculation unit 410 to calculate the initial values of the inspection suitabilities on the basis of the design information acquired in step S103 (S104). The calculation of the initial values of the inspection suitabilities is as described above, and thus a description thereof is omitted here.

Next, the inspection management device 40 uses the sample image acquisition unit 430 to acquire the sample images of the substrate subject to inspection captured in step S102 from the data server 30 (S105). Subsequently, the inspection management device 40 uses the image information reflection unit 412 of the inspection suitability calculation unit 410 to calculate corrected inspection suitabilities on the basis of the sample image information acquired in step S105 (S106). The calculation of the corrected inspection suitabilities by the image information reflection unit 412 is as described above, and thus a description thereof is omitted here.

Next, the inspection management device 40 uses the history information acquisition unit 440 to acquire, from the data server 30, information of past inspection history including inspection results of false negatives and/or false positives related to components of the same types as the components mounted on the substrate (S107). Subsequently, the inspection management device 40 uses the history information reflection unit 413 of the inspection suitability calculation unit 410 to calculate corrected inspection suitabilities on the basis of the history information acquired in step S107 (S108). The calculation of the corrected inspection suitabilities by the history information reflection unit 413 is as described above, and thus a description thereof is omitted here.

Next, the inspection management device 40 uses the inspection program creation unit 450 to update the initial program using the inspection suitabilities calculated by the processing from step S104 to step S108. More specifically, first, for each inspection item related to each component mounted on the substrate, the inspection program creation unit 450 makes an inspection ON/OFF determination as to whether inspections are to be performed by the appearance inspection device 10 and the X-ray inspection device 20 (S109). Specifically, inspection ON/OFF is determined for each inspection device such that the same inspection item is not redundantly inspected by the appearance inspection device 10 and the X-ray inspection device 20 to the extent possible, while ensuring coverage such that a required number of inspections is performed for all components mounted on the substrate. This makes it possible to improve the efficiency of the inspection and reduce the occurrence of a situation where an inspection having low inspection suitability is performed and results in overdetection.

Note that the ON/OFF setting of an inspection item can be determined by reflecting, for example, a rule such as the following. That is, the rule may be “for each possible defect type, turn ON inspection for inspection items having a high inspection suitability” or “for defect types having only inspection items with a low inspection suitability in each inspection device (e.g., appearance inspection suitability=5, X-ray inspection suitability=4, etc.), turn ON inspection by both inspection devices to prevent false positives,” or the like. Further, it is also possible to set flexible settings for different cases, such as “for front fillet inspection, perform inspection by the X-ray inspection device 20 only when the appearance inspection device 10 judges that the front fillet is defective.”

Subsequently, the inspection management device 40 checks whether the inspection program including the inspection ON/OFF settings determined in step S109 can be updated to further reduce line takt (S110). More specifically, in a case in which the inspection suitabilities of both the appearance inspection device 10 and the X-ray inspection device 20 satisfy a predetermined criterion and the inspection accuracy of the target inspection item is ensured in either case (e.g., appearance inspection suitability=8, X-ray inspection suitability=8), the ON/OFF setting of the inspection is updated such that the line takt of the entire inspection processing is minimized (that is, such that the efficiency is improved). For example, the inspection program can be updated on the basis of a criterion such as “perform inspection by the inspection device having an imaging field number that will not increase with inspection of the inspection item” or “estimate the time required for inspection of a similar inspection item with reference to past history information and perform inspection using the device that will not cause a bottleneck.”

The inspection management device 40 stores the inspection program thus created (updated) in the data server 30 (or each inspection device) (S111), and ends the series of inspection program creation processing. Further, the appearance inspection device 10 and the X-ray inspection device 20 inspect the substrate in accordance with the inspection program.

With the inspection management system of the present embodiment as described above, in an inspection system of the component-mounted substrate including the appearance inspection device and the X-ray inspection device, it is possible to calculate inspection suitabilities for each inspection item related to each component mounted on the substrate, and create, on the basis of the inspection suitabilities, an inspection program by which efficient inspection can be performed while ensuring inspection coverage. As a result, inspection efficiency can be improved while ensuring inspection accuracy.

### Others

The examples described above are merely illustrative of the present invention, and the present invention is not limited to the specific aspects described above. The present invention can be modified and combined in various ways within the scope of the technical idea of the present invention. For example, although the system in each of the examples described above includes two types of inspection devices corresponding to two types of imaging units, the present invention is also applicable to a system further including another inspection device including an imaging unit. Conversely, the system may have a configuration in which one inspection device is provided with a plurality of imaging units and a plurality of inspection units corresponding to the imaging units. For example, although described as a system that includes an inspection device in the examples described above, the present invention can also be regarded as a management device of an inspection system including an inspection device such as that described above.

Further, in the flow of the inspection program creation processing of the embodiment described above, naturally, the order of processing from step S105 to step S108 may be changed. Furthermore, any one or all of the processes of step S106, step S108, and step S110 need not be performed.

Further, although the embodiment described above has a configuration in which the inspection management device 40 for creating the inspection program is provided separately from the appearance inspection device 10 and the X-ray inspection device 20, each functional unit of the inspection management device 40 may be provided in either the appearance inspection device 10 or the X-ray inspection device 20 to perform the processing of each step described above without providing the inspection management device 40 separately.

Further, in the embodiments described above, although the appearance inspection device 10 is described as using an inspection method that is a combination of the phase shift method and the color highlight method, the device may be an appearance inspection device that performs inspection using only the phase shift method or only the color highlight method.

Further, the present invention is not limited to the combination of the appearance inspection device and the X-ray inspection device, and is also applicable to a combination of a laser scanning measurement device and the X-ray inspection device.

### <Supplementary Note 1>

An inspection system (1) including:
(1+n) types of imaging units (110, 210) each configured to capture an image of a component-mounted substrate that is an inspection target and acquire image data; (1+m) types of inspection units (10, 20) each configured to perform, on the basis of (1+n) types of the image data respectively acquired by the (1+n) types of imaging units, an inspection corresponding to each of the (1+n) types of image data;
an inspection suitability calculation unit (410) configured to calculate, for each of inspection items related to each of components mounted on the component-mounted substrate, inspection suitabilities each indicating a suitability of each of (1+m) types of the inspections performed by the (1+m) types of inspection units for detecting an abnormality according to the inspection item; and
an inspection program creation unit (450) configured to create or update an inspection program for the component-mounted substrate,
wherein the inspection program creation unit determines, on the basis of the inspection suitabilities, whether to perform each of the (1+m) types of inspections for each of the inspection items related to each of the components mounted on the component-mounted substrate.

### <Supplementary Note 2>

An inspection management device that is a device (93) configured to manage an inspection by an inspection system (9) including (1+n) types of imaging units (911, 921) each configured to capture an image of a component-mounted substrate (O) that is an inspection target and acquire image data and (1+m) types of inspection units (91, 92) each configured to perform, on the basis of (1+n) types of the image data respectively acquired by the (1+n) types of imaging units, an inspection corresponding to each of the (1+n) types of image data, the inspection management device including:
an inspection suitability calculation unit (931) configured to calculate, for each of inspection items related to each of components mounted on the component-mounted substrate, inspection suitabilities each indicating a suitability of each of (1+m) types of the inspections performed by the (1+m) types of inspection units for detecting an abnormality according to the inspection item; and
an inspection program creation unit (932) configured to create or update an inspection program for the component-mounted substrate,
wherein the inspection program creation unit determines, on the basis of the inspection suitabilities, whether to perform each of the (1+m) types of inspections for each of the inspection items related to each of the components mounted on the component-mounted substrate.

### <Supplementary Note 3>

An inspection program creation method for an inspection system including (1+n) types of imaging units each configured to capture an image of a component-mounted substrate that is an inspection target and acquire image data and (1+m) types of inspection units each configured to perform, on the basis of (1+n) types of the image data respectively acquired by the (1+n) types of imaging units, an inspection corresponding to each of the (1+n) types of image data, the inspection program creation method including:
an inspection suitability calculation step (S104, S106, S108) of calculating, for each of inspection items related to each of components mounted on the component-mounted substrate, inspection suitabilities each indicating a suitability of each of (1+m) types of the inspections performed by the (1+m) types of inspection units for detecting an abnormality according to the inspection item; and
an execution inspection determination step (S109) of determining, on the basis of the inspection suitabilities, whether to perform each of the (1+m) types of inspections for each of the inspection items related to each of the components mounted on the component-mounted substrate.

### REFERENCE SIGNS LIST

1,9 substrate inspection system
10 appearance inspection device
110 appearance image capturing unit
120 appearance measurement unit
130 appearance inspection unit
20 X-ray inspection device
210 X-ray image capturing unit
220 X-ray measurement unit
230 X-ray inspection unit
30 data server
40,93 inspection management device
410,93 inspection suitability calculation unit
450,932 inspection program creation unit
91,92 inspection device
911,921 imaging unit
O component-mounted substrate

1. An inspection system comprising:
(1+n) types of imaging units each configured to capture an image of a component-mounted substrate that is an inspection target and acquire image data;
(1+m) types of inspection units each configured to perform, on the basis of (1+n) types of the image data respectively acquired by the (1+n) types of imaging units, an inspection corresponding to each of the (1+n) types of image data;
an inspection suitability calculation unit configured to calculate, for each of inspection items related to each of components mounted on the component-mounted substrate, inspection suitabilities each indicating a suitability of each of (1+m) types of the inspections performed by the (1+m) types of inspection units for detecting an abnormality according to the inspection item; and
an inspection program creation unit configured to create or update an inspection program for the component-mounted substrate,
wherein the inspection program creation unit determines, on the basis of the inspection suitabilities, whether to perform each of the (1+m) types of inspections for each of the inspection items related to each of the components mounted on the component-mounted substrate.

2. The inspection system according to claim 1, further comprising:
a sample image acquisition unit configured to acquire (1+n) types of sample images of the component-mounted substrate respectively captured by the (1+n) types of imaging units,
wherein the inspection suitability calculation unit includes a first suitability calculation unit configured to calculate the inspection suitabilities on the basis of the (1+n) types of sample images.

3. The inspection system according to claim 2,
wherein the first suitability calculation unit includes a trained model obtained by performing machine learning using a training data set including inspection image data related to the component-mounted substrate resulting in a false negative and/or a false positive in at least any one of the (1+m) types of inspections performed in the past.

4. The inspection system according to any one of claims 1 to 3, further comprising:
an inspection history acquisition unit configured to acquire inspection history information of the past including an inspection result of false negative and/or false positive related to components of the same types as the components mounted on the component-mounted substrate,
wherein the inspection suitability calculation unit includes a second suitability calculation unit configured to calculate the inspection suitabilities on the basis of the inspection history information.

5. The inspection system according to any one of claims 1 to 4, further comprising:
a design information acquisition unit configured to acquire design information related to the component-mounted substrate,
wherein the inspection suitability calculation unit includes an initial value calculation unit configured to calculate initial values of the inspection suitabilities on the basis of the design information.

6. The inspection system according to any one of claims 1 to 5,
wherein the inspection suitabilities are individually calculated in correspondence with each of the (1+m) types of inspections, and
the inspection suitability calculation unit calculates the inspection suitabilities of all of the (1+m) types of inspections for each of the inspection items related to each of the components.

7. The inspection system according to any one of claims 1 to 6,
wherein the inspection program creation unit determines whether to perform the (1+m) types of inspections for each of the inspection items related to each of the components on the basis of the inspection suitabilities such that at least any one of the (1+m) types of inspections is performed for each of the inspection items related to each of the components mounted on the component-mounted substrate and all of the (1+m) types of inspections are performed for the inspection item for which none of the inspection suitabilities of the (1+m) types of inspections has met a predetermined criterion.

8. The inspection system according to any one of claims 1 to 6,
wherein the inspection program creation unit determines to perform any one of the (1+m) types of inspections to minimize line takt related to inspection of the component-mounted substrate for the inspection item for which a difference between the inspection suitabilities of the (1+m) types of inspections is within a predetermined range.

9. The inspection system according to any one of claims 1 to 5,
wherein the (1+n) types of imaging units include a first imaging unit that is a visible light camera and a second imaging unit that is an X-ray camera, and
the (1+m) types of inspections include a first inspection based on first image data acquired by the first imaging unit and a second inspection based on second image data acquired by the second imaging unit.

10. An inspection management device that is a device configured to manage an inspection by an inspection system including (1+n) types of imaging units each configured to capture an image of a component-mounted substrate that is an inspection target and acquire image data and (1+m) types of inspection units each configured to perform, on the basis of (1+n) types of the image data respectively acquired by the (1+n) types of imaging units, an inspection corresponding to each of the (1+n) types of image data, the inspection management device comprising:
an inspection suitability calculation unit configured to calculate, for each of inspection items related to each of components mounted on the component-mounted substrate, inspection suitabilities each indicating a suitability of each of (1+m) types of the inspections performed by the (1+m) types of inspection units for detecting an abnormality according to the inspection item; and
an inspection program creation unit configured to create or update an inspection program for the component-mounted substrate,
wherein the inspection program creation unit determines, on the basis of the inspection suitabilities, whether to perform each of the (1+m) types of inspections for each of the inspection items related to each of the components mounted on the component-mounted substrate.

11. An inspection program creation method for an inspection system including (1+n) types of imaging units each configured to capture an image of a component-mounted substrate that is an inspection target and acquire image data and (1+m) types of inspection units each configured to perform, on the basis of (1+n) types of the image data respectively acquired by the (1+n) types of imaging units, an inspection corresponding to each of the (1+n) types of image data, the inspection program creation method comprising:
an inspection suitability calculation step of calculating, for each of inspection items related to each of components mounted on the component-mounted substrate, inspection suitabilities each indicating a suitability of each of (1+m) types of the inspections performed by the (1+m) types of inspection units for detecting an abnormality according to the inspection item; and
an execution inspection determination step of determining, on the basis of the inspection suitabilities, whether to perform each of the (1+m) types of inspections for each of the inspection items related to each of the components mounted on the component-mounted substrate.

12. The inspection program creation method according to claim 11, further comprising:
a sample image acquisition step of acquiring (1+n) types of sample images of the component-mounted substrate respectively captured by the (1+n) types of imaging units,
wherein the inspection suitability calculation step includes a first suitability calculation step of calculating the inspection suitabilities on the basis of the (1+n) types of sample images.

13. The inspection program creation method according to claim 11 or 12, further comprising:
an inspection history acquisition step of acquiring inspection history information of the past including an inspection result of false negative and/or false positive related to components of the same types as the components mounted on the component-mounted substrate,
wherein the inspection suitability calculation step includes a second suitability calculation step of calculating the inspection suitabilities on the basis of the inspection history information.

14. The inspection program creation method according to any one of claims 11 to 13, further comprising:
a design information acquisition step of acquiring design information related to the component-mounted substrate,
wherein the inspection suitability calculation step includes an initial value calculation step of calculating initial values of the inspection suitabilities on the basis of the design information.

15. A program for causing a computer to execute each step of the inspection program creation method according to any one of claims 11 to 14.
